(19) United States
(12) Patent Application Publication
(10) Pub. No.: US 2013/0175537 A1
(43) Pub. Date: Jul. 11, 2013

(54) HIGH ELECTRON MOBILITY GaN-BASED TRANSISTOR STRUCTURE

(71) Applicants: EDWARD YI CHANG, HSINCHU COUNTY (TW); CHIA-HUA CHANG, TAICHUNG CITY (TW); YUEH-CHIN LIN, NEW TAIPEI CITY (TW); YU KONG CHEN, NEW TAIPEI CITY (TW); SHIH-CHIEN LIU, HSINCHU CITY (TW)

(72) Inventors: EDWARD YI CHANG, HSINCHU COUNTY (TW); CHIA-HUA CHANG, TAICHUNG CITY (TW); YUEH-CHIN LIN, NEW TAIPEI CITY (TW); YU KONG CHEN, NEW TAIPEI CITY (TW); SHIH-CHIEN LIU, HSINCHU CITY (TW)

(73) Assignee: NATIONAL CHIAO TUNG UNIVERSITY, HSINCHU CITY (TW)

(21) Appl. No.: 13/455,527

(22) Filed: Apr. 25, 2012

(30) Foreign Application Priority Data
Jan. 10, 2012 (TW) 101100964

(51) Int. Cl. H01L 29/20

(52) U.S. Cl. 257/76; 257/E29.089

(57) ABSTRACT

A high electron mobility GaN-based transistor structure comprises a substrate, an epitaxial GaN layer formed on the substrate, at least one ohmic contact layer formed on the epitaxial GaN layer, a metallic gate layer formed on the epitaxial GaN layer, and a diffusion barrier layer interposed between the metallic gate layer and the epitaxial GaN layer. The diffusion barrier layer hinders metallic atoms of the metallic gate layer from diffusing into the epitaxial GaN layer, whereby are improved the electric characteristics and reliability of the GaN-based transistor.

### BACKGROUND OF THE INVENTION

1. Field of the Invention

The present invention relates to a GaN-based transistor structure, particularly to a high electron mobility GaN-based transistor structure.

2. Description of the Related Art

The GaN (Gallium Nitride)-based transistor composed of IIIA group elements and VA group elements is a recent development in semiconductor devices. The GaN-based transistor can tolerate great current and sustain high voltage. Further, the GaN-based transistor has very low turn-on resistance and very short switching time. Therefore, the GaN-based transistor is also a promising candidate for power transistors.

HEMT (High Electron Mobility Transistor) is a power transistor primarily made of gallium nitride. The GaN-based HEMT features a high breakdown voltage and a large energy gap. Therefore, the GaN-based HEMT can operate in an environment of high temperature, high current and/or high voltage.

The metallic gate of the GaN-based transistor is conventionally made of gold. Because the price of gold grows higher persistently, the metallic gate made of another metal has been a tendency.

Copper features low price and high conductivity and thus may function as the metallic gate of the GaN-based transistor. However, the

GaN-based transistor using a copper gate will degenerate in an environment of high temperature, high current and/or high voltage.

During the high-temperature annealing process, copper diffuses into the GaN-based HEMT and degrades the electron conduction property. When transistor operates at forward bias and high current, leakage current will easily increase from the gate, which will degrade breakdown voltage and make the transistor malfunction. As a result, how the GaN-based transistor using a copper gate can be applied to the operating environment and condition of the GaN-based HEMT is highly limited.

### SUMMARY OF THE INVENTION

The primary objective of the present invention is to provide a high electron mobility GaN-based transistor structure, wherein a diffusion barrier layer is used to promote the performance and reliability of the element.

Another objective of the present invention is to provide a high electron mobility GaN-based transistor structure, wherein a diffusion barrier layer is deposited below the metallic gate to hinder metallic atoms from diffusing into the GaN-based transistor.

A further objective of the present invention is to provide a high electron mobility GaN-based transistor structure, whereby is overcome the conventional problem that copper will easily diffuse into the semiconductor of a copper gate GaN-based transistor, and whereby is increased the breakdown voltage and improved the characteristic of the turn-on current.

To achieve the abovementioned objectives, the present invention proposes a high electron mobility GaN-based transistor structure, which comprises a substrate, an epitaxial GaN layer formed on the substrate, at least one ohmic contact layer formed on the epitaxial GaN layer, a metallic gate layer formed on the epitaxial GaN layer, and a diffusion barrier layer interposed between the metallic gate layer and the epitaxial GaN layer and used to hinder metallic atoms from diffusing into epitaxy layer. In one embodiment, the metallic gate can be made of copper.

In one embodiment, the diffusion barrier layer is made of titanium nitride or tungsten nitride.

In one embodiment, the diffusion barrier layer has a thickness of 5-100 nm.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1A schematically shows a high electron mobility GaN-based transistor structure according to one embodiment of the present invention;

FIG. 1B schematically shows a high electron mobility GaN-based transistor structure according to another embodiment of the present invention;

FIG. 1C schematically shows a high electron mobility GaN-based transistor structure according to a further embodiment of the present invention;

FIG. 2A and FIG. 2B show the DC characteristic of a high electron mobility GaN-based transistor structure using a WN/Cu gate according to one embodiment of the present invention;

FIG. 3A and FIG. 3B show the DC characteristic of a high electron mobility GaN-based transistor structure using a TiN/Cu gate according to one embodiment of the present invention;

FIG. 4 shows the comparison of the breakdown voltage characteristics of a transistor merely using a Cu gate and a transistor using a WN/Cu gate according to one embodiment of the present invention; and

FIG. 5 shows the comparison of the leakage current characteristics of a transistor merely using a Cu gate, a transistor using a WN/Cu gate and a transistor using a TiN/Cu gate according to one embodiment of the present invention.

### DETAILED DESCRIPTION OF THE INVENTION

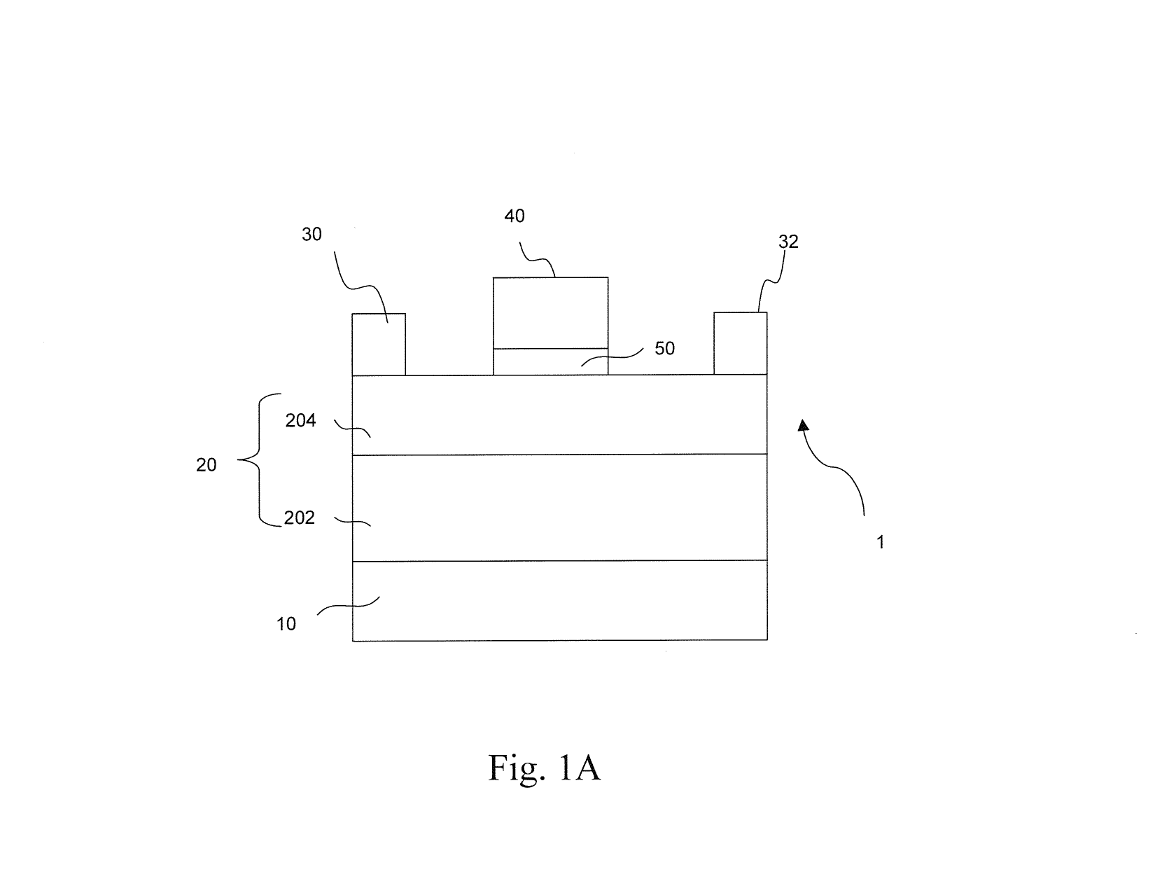

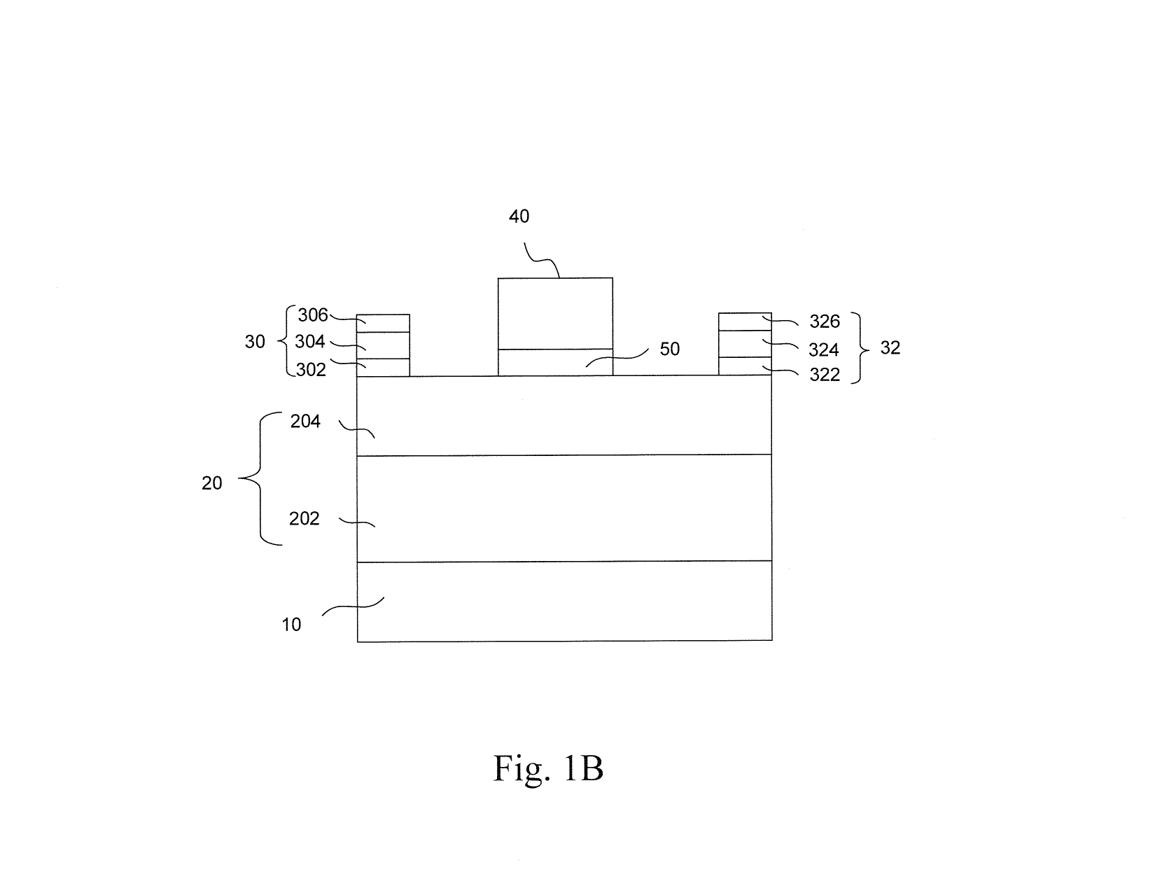

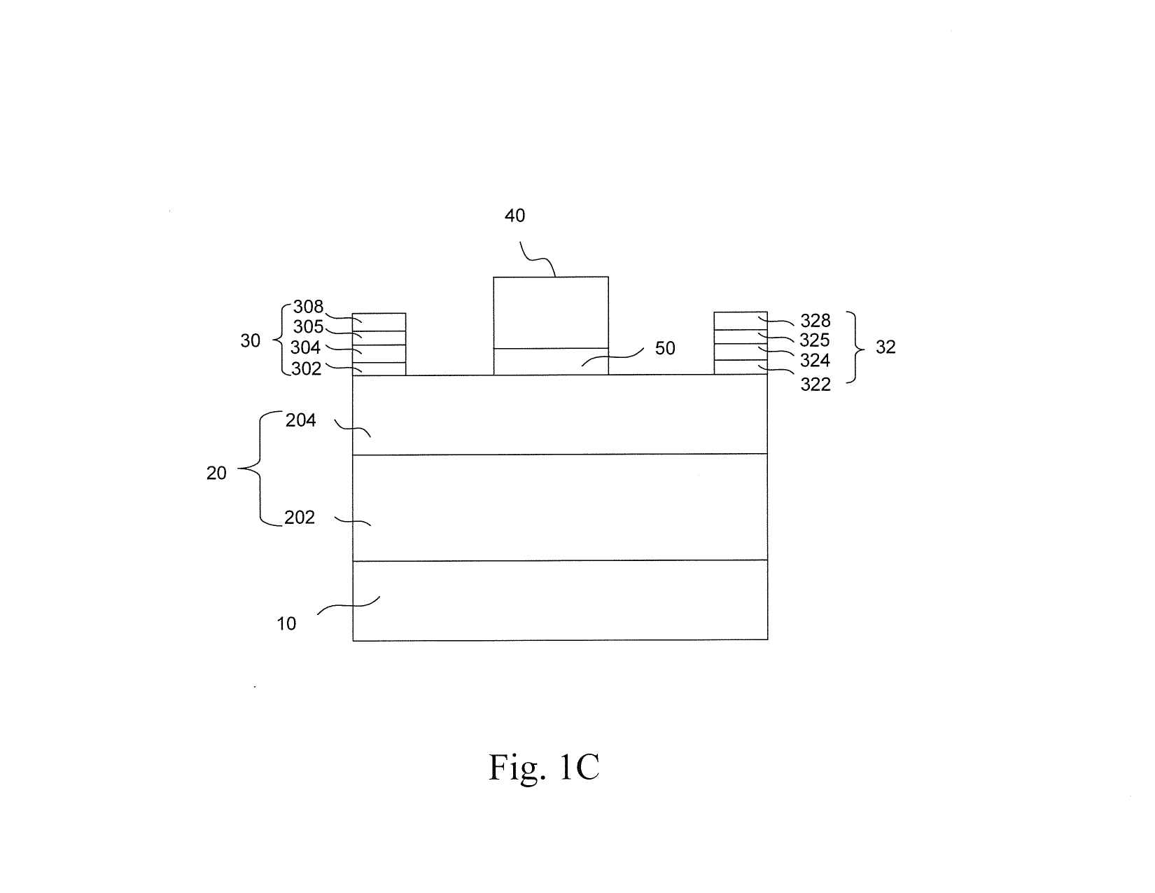

Refer to FIG. 1A schematically showing a high electron mobility GaN-based transistor structure according to one embodiment of the present invention.

The high electron mobility GaN-based transistor structure 1 according to one embodiment of the present invention, comprises a substrate 10, an epitaxial GaN layer 20 formed on the substrate 10, and ohmic contact layers 30 and 32 formed on the epitaxial GaN layer 20.

The epitaxial GaN layer 20 includes a GaN layer 202 formed on the substrate 10 and an aluminum gallium nitride (AlGaN) layer 204 formed on the GaN layer 202. The present invention neither limits the types and number of the epitaxial layers of the epitaxial GaN layer 20 nor constrains that the epitaxial GaN layer 20 should only have the GaN layer 202 and the AlGaN layer 204. In other embodiments, the epitaxial GaN layer 20 may further contain other epitaxial layers.

The ohmic contact layers 30 and 32 are formed on the epitaxial GaN layer 20 and respectively have ohmic-contact stack structures functioning as the source and drain of the GaN-based transistor structure 1.

Refer to FIG. 1B, which is a high electron mobility GaN-based transistor structure according to another embodiment of the present invention. In this embodiment, each ohmic-contact stack structure has a titanium layer 302 or 322, an aluminum layer 304 or 324, and a copper layer 306 or 326 in sequence from the epitaxial GaN layer 20.

In another embodiment, each ohmic-contact stack structure may also have a titanium layer and an aluminum layer in sequence from the epitaxial GaN layer 20.

Refer to FIG. 1C, which is a high electron mobility GaN-based transistor structure according to a further embodiment of the present invention. In this embodiment, each ohmic-contact stack structure has a titanium layer 302 or 322, an aluminum layer 304 or 324, a nickel layer 305 or 325, and a gold layer 308 or 328 in sequence from the epitaxial GaN layer 20.

In another embodiment, each ohmic-contact stack structure may also have a titanium layer, an aluminum layer, a molybdenum layer and a gold layer in sequence from the epitaxial GaN layer 20.

In still another embodiment, each ohmic-contact stack structure may also have a titanium layer, an aluminum layer, a nickel layer and a copper layer in sequence from the epitaxial GaN layer 20.

All the abovementioned embodiments are only to exemplify the present invention but not to limit the scope of the present invention.

According to one embodiment of the present invention, the high electron mobility GaN-based transistor structure 1 further comprises a metallic gate layer 40 and a diffusion barrier layer 50. The metallic gate layer 40 is normally made of copper and formed on the epitaxial GaN layer 20, functioning as the gate of the GaN-based transistor structure 1.

The diffusion barrier layer 50 is interposed between the metallic gate layer 40 and the epitaxial GaN layer 20 and used to hinder the metallic atoms of the metallic gate layer 40 from diffusing into the semiconductor. In one embodiment, the diffusion barrier layer 50 is made of titanium nitride (TiN) or tungsten nitride (WN), and used to hinder copper atoms of the metallic gate layer 40 from diffusing into the semiconductor.

In one embodiment, the diffusion barrier layer 50 is formed on the epitaxial GaN layer 20 in a way of a sputtering method, an evaporation method, or a CVD (Chemical Vapor Deposition) method. In one embodiment, the diffusion barrier layer 50 has a thickness of 5-100 nm.

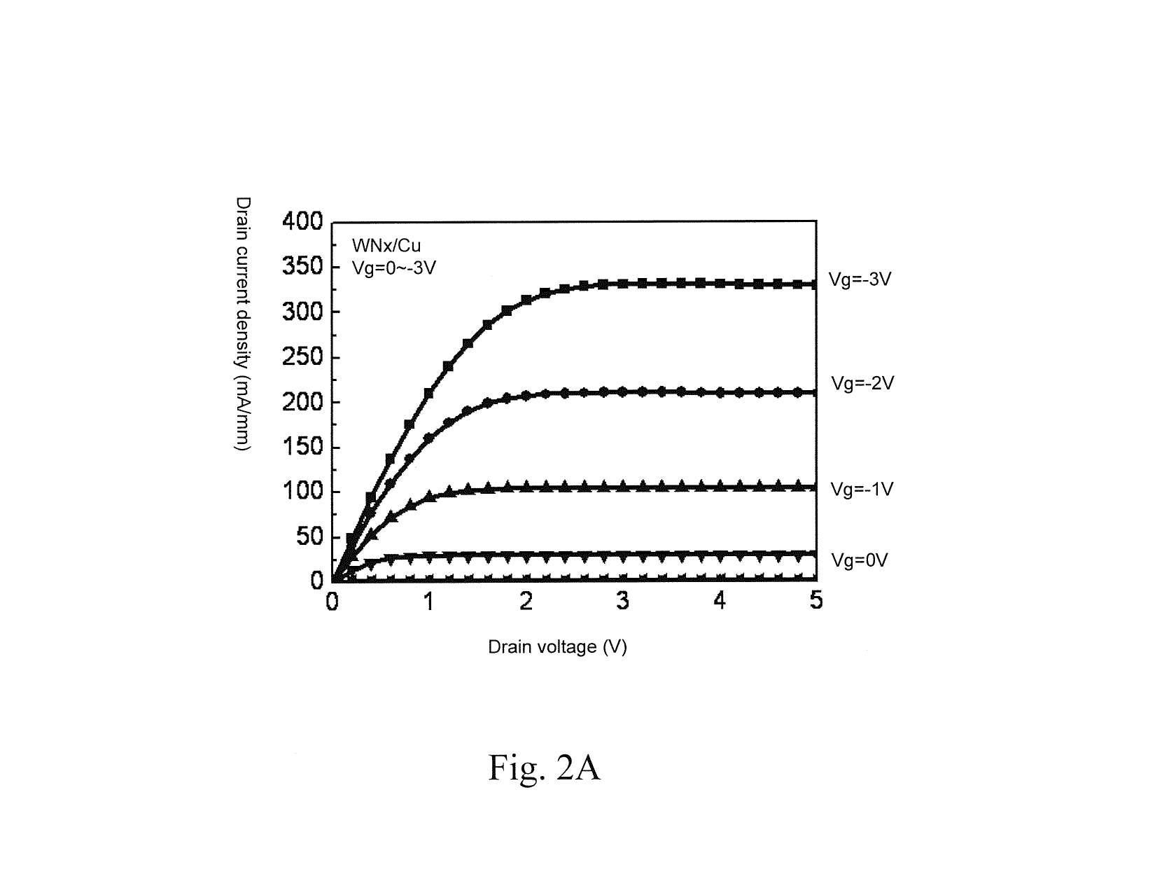

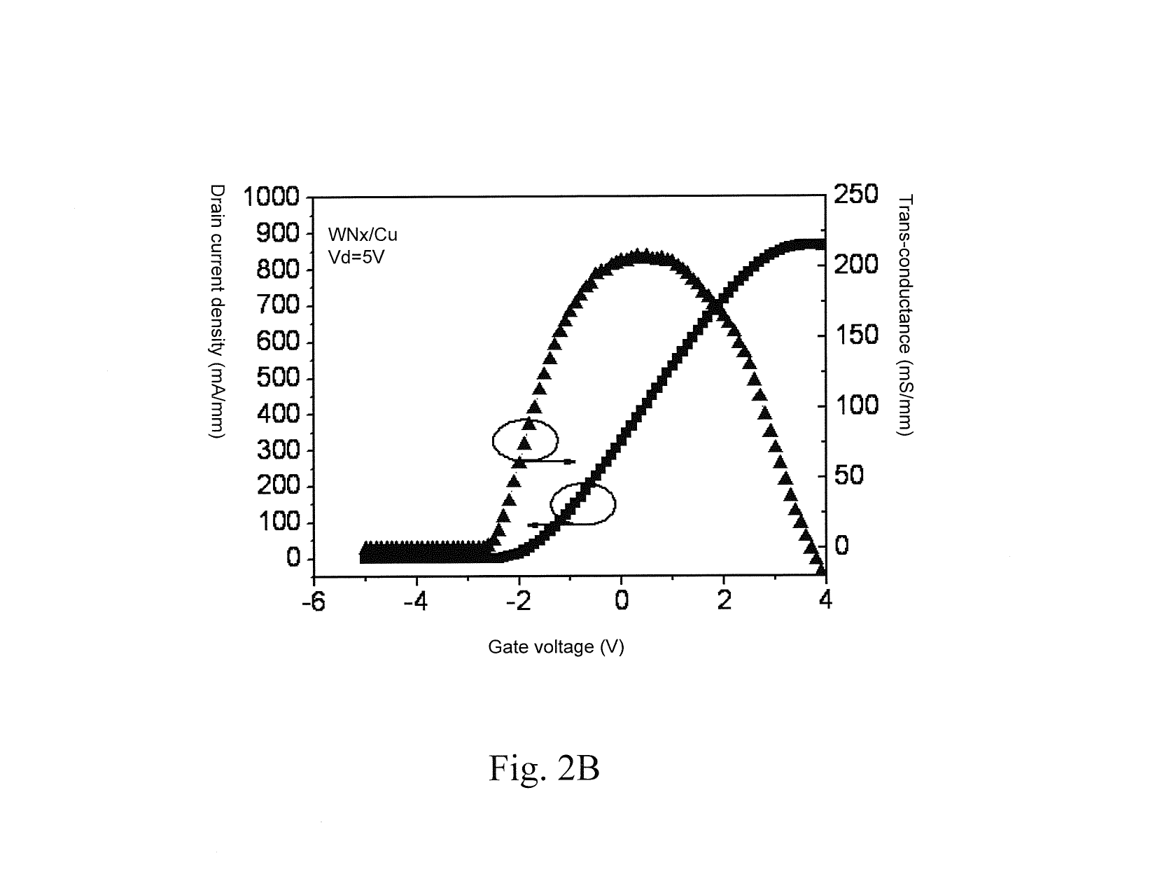

Refer to FIG. 2A and FIG. 2B showing the DC characteristic of a high electron mobility GaN-based transistor structure using a WN/Cu gate according to one embodiment of the present invention. It can be observed in FIG. 2A and FIG. 2B that the GaN-based HEMT of the present invention has well current characteristic and trans-conductance when it adopts a tungsten-nitride diffusion barrier layer.

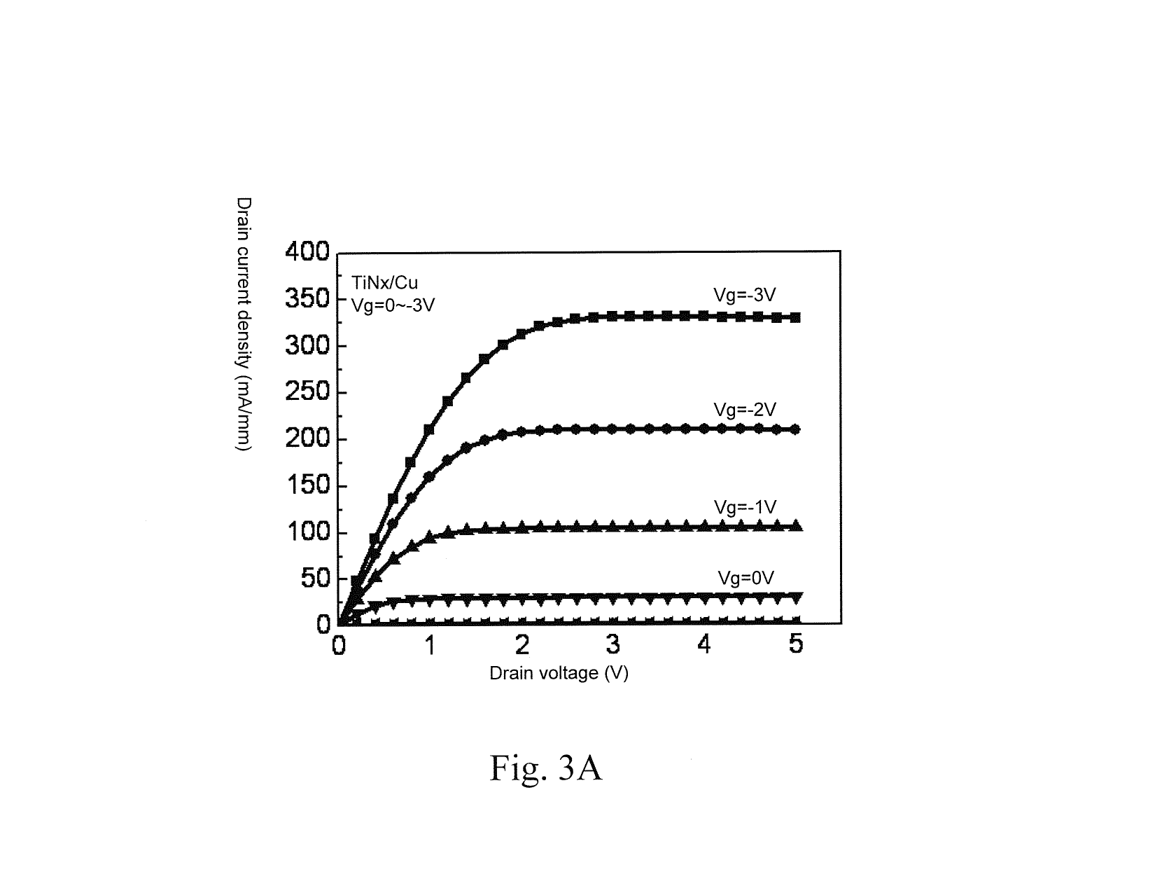

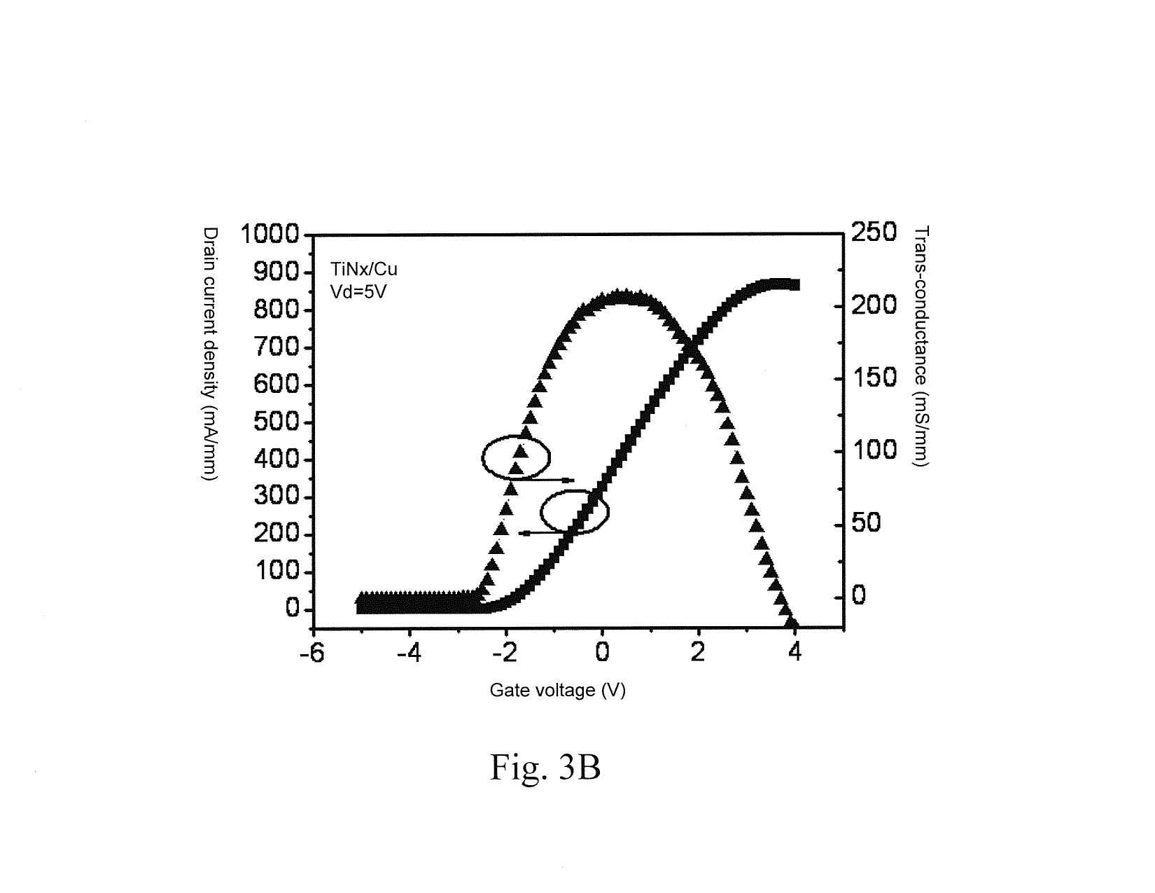

Refer to FIG. 3A and FIG. 3B showing the DC characteristic of a high electron mobility GaN-based transistor structure using a TiN/Cu gate according to one embodiment of the present invention. It can be observed in FIG. 3A and FIG. 3B that the GaN-based HEMT of the present invention also has well current characteristic and trans-conductance when it adopts a titanium-nitride diffusion barrier layer.

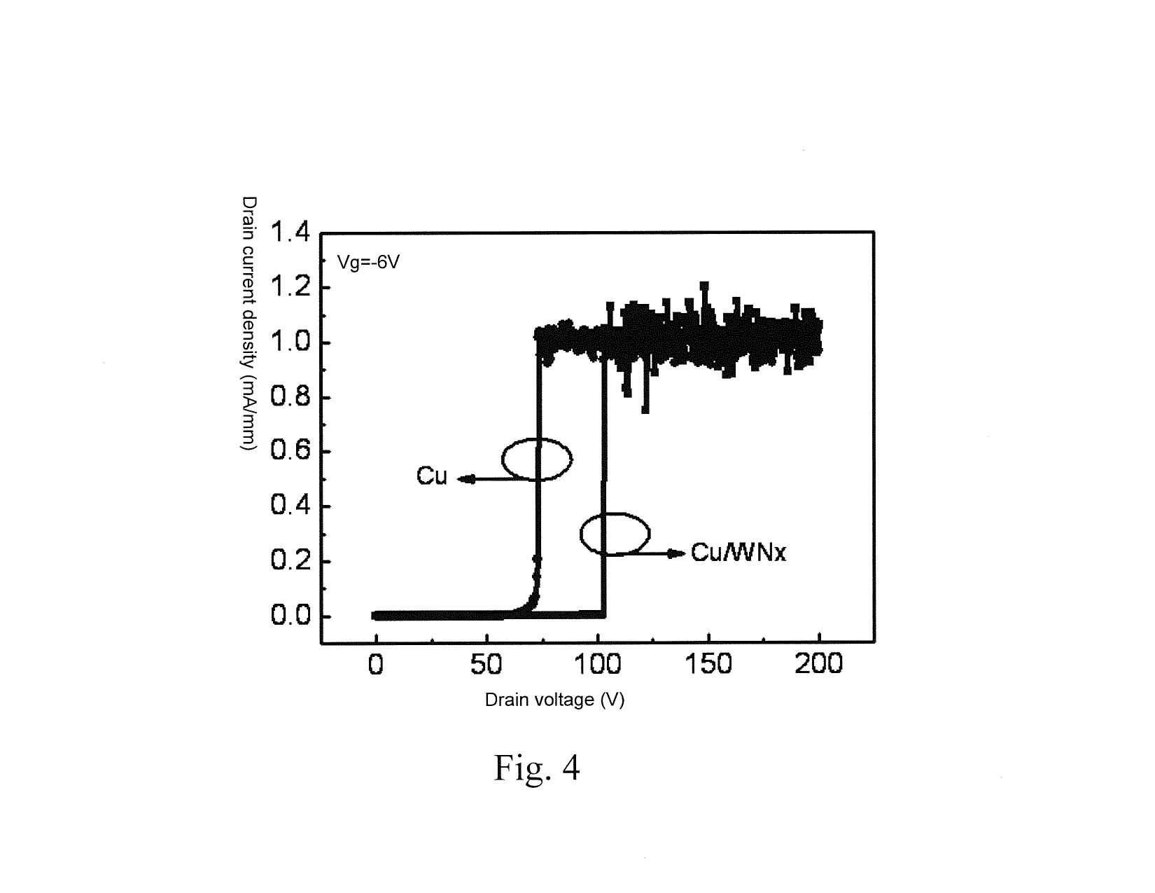

Further, refer to FIG. 4 showing the comparison of the breakdown voltage characteristics of a transistor merely using a copper gate and a transistor using a WN/Cu gate. It can be observed in FIG. 4 that the GaN-based HEMT using a WN/Cu gate of the present invention outperforms the transistor merely using a copper gate in the breakdown voltage characteristic by about 25%. Therefore, the WN/Cu gate structure of the present invention has better performance.

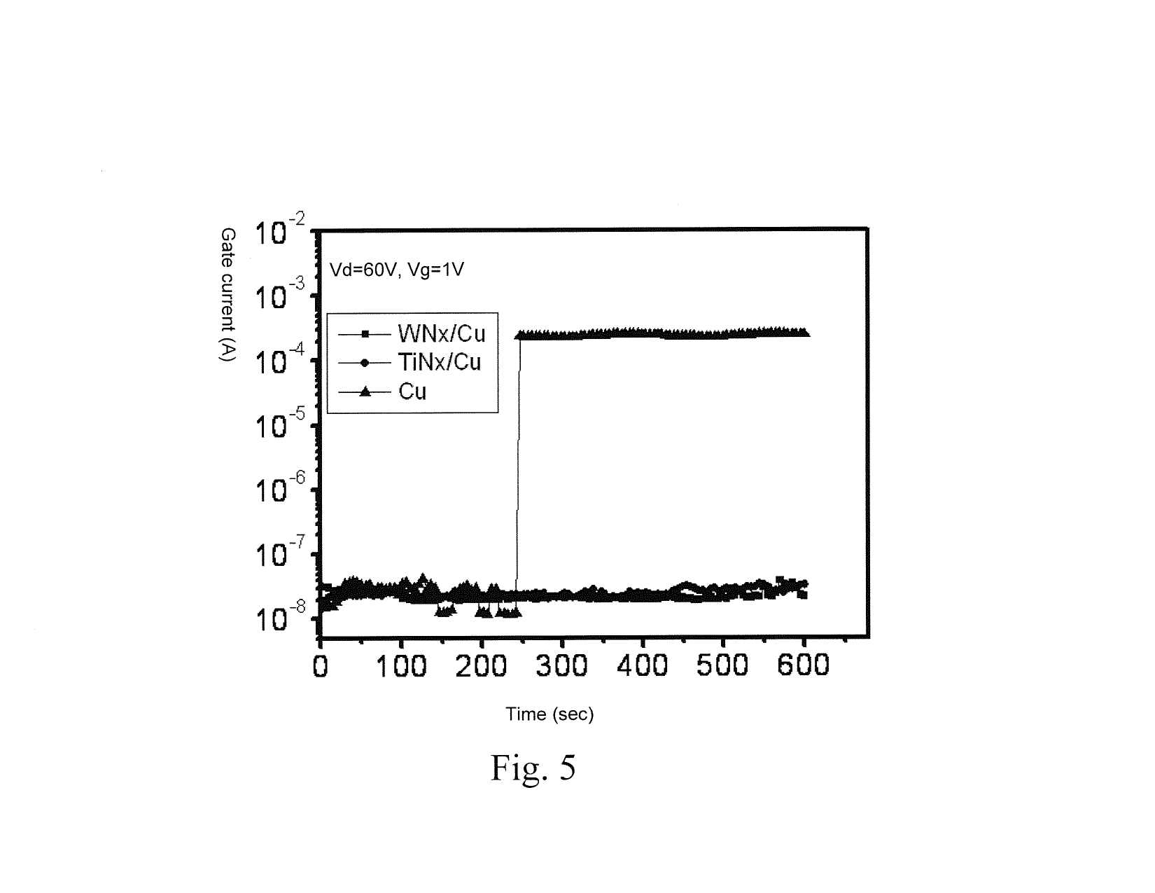

The Inventors also perform the on-state high-voltage tests on a transistor merely using a copper gate, a transistor using a WN/Cu gate, and a transistor using a TiN/Cu gate and record the leakage currents of each gate, wherein the drain is biased by a voltage of 60V(Vd=60V) and the gate is biased by a voltage of 1V (Vg=1V). The test results are shown in FIG. 5. When the test has been undertaken for 250 seconds, the leakage current of the transistor merely using a copper gate begins to rise steeply. However, the leakage currents of the transistor using a WN/Cu gate and the transistor using a TiN/Cu gate are still in a stable state when the test has been undertaken even for 600 seconds. The test results show that the WN/Cu gate structure and the TiN/Cu gate structure of the present invention outperform the conventional copper gate structure.

In conclusion, the present invention proposes a high electron mobility GaN-based transistor structure, wherein a diffusion barrier layer is deposited below the metallic gate to hinder the metallic atoms of the metallic gate from diffusing into the epitaxy layer. Compared with the conventional transistor merely using a copper gate, the transistor using a WN/Cu or TiN/Cu gate of the present invention has better performance in the breakdown voltage and the on-state characteristics.

The embodiments described above are to demonstrate the technical thought and characteristics of the present invention and enable the persons skilled in the art to understand, make and use the present invention. However, these embodiments are not intended to limit the scope of the present invention. Any equivalent modification or variation according to the spirit of the present invention is to be also included within the scope of the present invention.

What is claimed is:

1. A high electron mobility GaN-based transistor structure comprising a substrate
an epitaxial gallium nitride (GaN) layer formed on said substrate;
at least one ohmic contact layer formed on said epitaxial GaN layer;
a metallic gate layer formed on said epitaxial GaN layer; and
a diffusion barrier layer interposed between said metallic gate layer and said epitaxial GaN layer used to hinder metallic atoms of said metallic gate layer from diffusing into said epitaxial GaN layer.

2. The high electron mobility GaN-based transistor structure according to claim 1, wherein said epitaxial GaN layer further comprises
a GaN layer formed on said substrate; and
a gallium aluminum nitride (GaAlN) layer formed on said GaN layer.

3. The high electron mobility GaN-based transistor structure according to claim 1, wherein said at least one ohmic contact layer includes a plurality of ohmic-contact stack structures.

4. The high electron mobility GaN-based transistor structure according to claim 3, wherein each said ohmic-contact stack structure includes a titanium layer, an aluminum layer, a nickel layer and a gold layer.

5. The high electron mobility GaN-based transistor structure according to claim 3, wherein each said ohmic-contact stack structure includes a titanium layer, an aluminum layer, a molybdenum layer and a gold layer.

6. The high electron mobility GaN-based transistor structure according to claim 3, wherein each said ohmic-contact stack structure includes a titanium layer and an aluminum layer.

7. The high electron mobility GaN-based transistor structure according to claim 3, wherein each said ohmic-contact stack structure includes a titanium layer, an aluminum layer and a copper layer.

8. The high electron mobility GaN-based transistor structure according to claim 3, wherein each said ohmic-contact stack structure includes a titanium layer, an aluminum layer, a nickel layer and a copper layer.

9. The high electron mobility GaN-based transistor structure according to claim 1, wherein said metallic gate layer is made of copper.

10. The high electron mobility GaN-based transistor structure according to claim 1, wherein said diffusion barrier layer is made of titanium nitride or tungsten nitride.

11. The high electron mobility GaN-based transistor structure according to claim 1, wherein said diffusion barrier layer is formed on said epitaxial GaN layer with a sputtering method, an evaporation method or a chemical vapor deposition method.

12. The high electron mobility GaN-based transistor structure according to claim 1, wherein said diffusion barrier layer has a thickness of 5-100 nm.
